(19) United States
(12) Patent Application Publication
(10) Pub. No.: US 2011/0083720 A1
(43) Pub. Date: Apr. 14, 2011

(54) Concentrator photovoltaics device with positioning aid

(75) Inventor: Erich W. Merkle, Munchen (DE)

(73) Assignee: SOLARTEC AG, München (DE)

(21) Appl. No.: 12/161,425

(22) PCT Filed: Jan. 17, 2007
(86) PCT No.: PCT/DE2007/000102

§ 371 Date: Jul. 18, 2008

(30) Foreign Application Priority Data
Jan. 18, 2006 (DE) 10 2006 002 465.6
Jan. 17, 2007 (DE) PCT/DE2007/000102

(51) Int. Cl. H01L 31/052

(52) U.S. Cl. 136/246

(57) ABSTRACT

The invention relates to a photovoltaics device for directly converting solar energy to electric power. Said device comprises a housing (10), provided with at least one light entrance panel from a transparent material, a plurality of solar cells (5), arranged at a respective distance to the at least one light entrance panel on its side facing away from the sun in the interior of the housing (10) and having a smaller surface area that a light entrance surface of the light inlet panel. The light entrance panel is provided with an optical unit for concentrating or bundling the solar radiation incident through the light entrance surface onto the smaller surface areas of the solar cells (5). The housing (10) comprises an injection-molded part from a first material that forms the lateral walls.

The invention relates to a PV device, as known, for example, from the article A. W. Bett et al: FLATCON AND FLASHCON CONCEPTS FOR HIGH CONCENTRATION PV. Proc. 19^{th} European Photovoltaic Solar Energy Conference and Exhibition, Paris, France, 2004, page 2488.

For further details with regard to concentrator photovoltaics devices of this type, reference is made to the German patent application DE 10 2005 033 272.2 of the Applicant, which is not published prior art.

In the area of use of solar energy, it has been known for about 50 years that solar energy can be converted into electrical current by silicon. In solar cells which are currently conventional, monocrystalline or multicrystalline silicon is generally used. The power of these solar cells is relatively low, however, as they only convert a limited spectrum of the impinging radiation into electrical current. Great success has been achieved in recent years with high power PV cells made of high-quality semiconductor connections (III-IV semiconductor material), such as, for example, gallium arsenide (GaAs) towards significantly higher efficiency with over 39% conversion of the solar radiation.

Cells of this type based on semiconductor material can be constructed step-wise as tandem cells, triple cells or quadruple stack cells and thus use a broader light frequency spectrum.

Large-area production of such cells is very expensive, however. The approach was therefore selected of concentrating the incident sunlight onto a very small surface area of, for example, below 1 mm². A solar cell is then only necessary for this small surface area. The use of material may then be below 1% compared to planar use of such cells. Because of the concentration, the high light efficiency of high power PV cells of currently above 39% can be utilised. Since only the connection of a plurality of solar units allows economical use of a PV system of this type, these are preferably combined to form a PV concentrator module.

The previously used systems predominantly work with relatively large Fresnel lenses with a relatively large focal length and this leads to a considerably thickness of the modules. Their combination to form powerful units (solar power plants) leads to a very high weight (1t weight per kilowatt) so the requirements of the statics of a tracking system with which the PV modules are made to track the sunlight, are considerable, for example, because of the wind forces. Because of the high outlay, the known concentrator systems did not become widespread despite the high growth of photovoltaic current generation.

Although concentrator systems with small-area optics have also been presented in recent years, which sometimes also allowed a more than 500-fold concentration of the sunlight, very many cells are necessary, however in this case (for example about 1.5 million cells for 500 kW output, 30% “output” of the solar cells) to produce an economically operating solar power plant. Until now, the removal of high heat concentrations to the outside and the protection of the sensitive solar cells against environmental influences, in particular penetrating moisture and gases, were a problem.

Furthermore, the structural problems of the exact relative positioning of the concentrator optics and the respective solar cell such that each cell is located in the corresponding focal point, in the previously selected approaches, give rise to a substantial outlay, which substantially eats up the intended cost saving. The problems of the relative positioning of the solar cells with respect to the concentrator optics limit the possible concentration and therefore the size of the solar cells.

A relative positioning of the concentrator optics relative to the solar cells already works tolerably well in laboratory tests. However, it is essential to also provide constructions and production methods, with which as high a light intensity as possible can be utilised for as long as possible with as low an outlay as possible, in practice.

The precise construction of a PV concentrator module and therefore the precise positioning of the solar cells relative to the concentrator optics in the prior art is influenced by many factors, including ones which change in operation and therefore can only be managed in practice with difficulty.

The invention is based on the object of constructing a photovoltaics device according to the preamble of the accompanying claim 1, which uses the advantages of PV concentrator technology in such a way that the aforementioned disadvantages are avoided and a precise construction of a PV device and therefore the relative positioning of the concentrator optics with respect to the solar cells is achieved, and that a photovoltaics device can thus be made in series production with low outlay.

This object is achieved by a concentrator photovoltaics device with the features of the accompanying claim 1.

Advantageous configurations of the invention are the subject of the sub-claims.

The photovoltaics device according to the invention for direct conversion of solar energy into electrical energy has solar cells which are in each case arranged at a spacing from the at least one light entrance panel on the side thereof remote from the sun in the interior of a housing and take up a smaller surface area than a light entrance surface of the light entrance panel. In this case, the light entrance panel has an optical unit for concentrating or focusing the solar radiation entering through the light entrance surface of the light entrance panel onto the smaller surface areas of the solar cells. In contrast to known photovoltaics devices for the direct conversion of solar energy into electrical energy, the housing has an injection moulding made of a first material, which is suitable for injection moulding, to form the side walls.

When manufacturing the side walls by the injection moulding method, the side walls may receive a precise shape or dimensioning, which leads to increased precision in the relative positioning of such manufactured side walls relative to the associated light entrance panel in an automated construction method of a photovoltaics device according to the invention by means of conventionally used positioning methods for injection mouldings. By the injection moulding method, very complex housing parts can also be produced easily and in a high industrial volume very economically. This achieves a relatively large diversity of design possibilities; and many functions, such as the accommodation of channels, positioning, sealing and weather protection, can easily be achieved.

The light entrance panel can easily be fastened to the housing by adhesion.

For a further and long-term stabilisation of the relative position of the light entrance panel relative to the housing, the housing may laterally have a valve for the introduction of gas into the housing or removal of gas and/or vapour from the housing. With the aid of a valve of this type, air and/or steam can be removed from the housing and a negative pressure thus produced in the housing, so the light entrance panel is additionally fixed as a result of the difference between the external pressure and the pressure in the interior of the housing on the side of the housing facing the light entrance panel.

The injection moulding may be formed from a non-transparent material, which leads to a reduced heat transport through heat radiation from outside to the solar cells.

The injection moulding is advantageously formed from a plastics material mixture. Because of its great formability, plastics material is particularly suitable as the moulding material in the injection moulding method. Plastics material is very economical and light-weight, so, as a whole, the device becomes more favourable and lighter. Moreover, the tracking devices (tracking the sun) can be made simpler because of the low weight.

The use of glass fibre-reinforced plastics material, in particular, when manufacturing the injection moulding leads to an increase in the service life and the operating reliability of a photovoltaics device according to the invention for the direct conversion of solar energy into electrical energy as glass fibre-reinforced plastics material, in particular, has high breaking resistance and temperature resistance. In particular, a plastics material mixture may be selected which has a specific coefficient of expansion, which leads to a particularly suitable or advantageous expansion behaviour of the housing.

An advantageous expansion behaviour of the housing is achieved, for example, by using an injection moulding, which is formed from a glass fibre-reinforced plastics material.

Particularly advantageous expansion behaviour of the housing is achieved by the use of an injection moulding, which is formed from glass fibre-reinforced plastics material with a glass fibre proportion of 10 to 50% by weight.

Glass fibre-reinforced plastics materials are also economical, temperature-resistant and have a high breaking elongation and therefore a low susceptibility to breaking, so their use in manufacturing the housing leads to an increased service life and more economical production of a photovoltaics device according to the invention.

In addition, the injection moulding may be formed from a dyed material, in particular dyed plastics material or be subsequently dyed, for example by spraying or dipping. The presence of the coloured injection moulding means that a photovoltaics device according to the invention is produced particularly simply and favourably in that the relative positioning of the housing on the light entrance panel takes place with the aid of orientation on an upper side of the injection moulding of the housing facing the light entrance panel. No further positioning features are necessary.

In addition, the housing may have an additional upper peripheral housing frame facing the light entrance panel and/or lower peripheral housing frame remote from the light entrance panel, which is configured as an injection moulding, in particular. The upper frame allows even more precise positioning of the housing relative to the light entrance panel by the facilitated recognition of the upper part of the housing facing the light entrance panel, by means of the upper frame. The upper lateral peripheral frame is located in the space which identifies and directly laterally adjoins directly over the housing on its side facing the light entrance surface. The lower lateral peripheral frame may be located in the space identifying and directly laterally adjoining directly below the housing on its side remote from the light entrance surface. The lower frame may allow, in a similar manner to the upper frame, a facilitated and more precise positioning of the housing from below, i.e. from the side remote from the light entrance surface, in an automated and therefore more economical construction method of a photovoltaics device according to the invention. The upper frame is also used for an improved sealing possibility of the interior of the housing from above by the light entrance panel. The lower frame may be used for an improved sealing possibility for the interior of the housing from below.

In the injection moulding method, the upper frame may receive a positioning mark on its upper corner on the side facing the light entrance surface. In this case, the production costs of a photovoltaics device according to the invention for direct conversion of solar energy into electrical energy are reduced as the relative positioning of the housing with respect to the light entrance panel takes place only with the aid of the positioning of the positioning mark of the upper frame relative to the corresponding corner or the positioning mark of the associated light entrance panel present on the corresponding corner. In the injection moulding method, the lower frame of a lower corner corresponding to the upper corner may also receive a positioning mark on the side remote from the light entrance surface. In this case, the production costs of a photovoltaics device according to the invention for the direct conversion of solar energy into electrical energy are still further reduced as the positioning of the housing from below, i.e. from the side remote from the light entrance panel only takes place with the aid of the positioning of the positioning mark on the lower frame.

The injection moulding is advantageously a metal injection moulding, in particular made of light metal, such as aluminium, or a part manufactured by the MIM method (from the English: metal injection moulding). In the MIM method, metal powder is heated with a plastics material and then injected into a mould. In other words, a part manufactured by the MIM method has both the advantages of the use of metal and the advantages of the use of plastics material.

A photovoltaics device according to the invention with a low weight as a consequence of the use of light metal for the housing, has the advantage that the tracking of such light modules with respect to the light source is simplified.

As an alternative, the housing, on the side opposing the light entrance panel, may have at least one base panel made of second material with a greater heat conductivity than the first material. The greater heat conductivity of the base panel compared to the heat conductivity of the housing, leads to good dissipation of the heat, which is produced during operation, from the solar cells to the outside. The base panel may be formed from aluminium or another material, aluminium and steel having very good heat conductivity.

The base panel may be dimensioned in such a way that it seals the housing from below. Good sealing of the interior of the housing leads to better protection of the solar cells from environmental influences, as good sealing of the housing from below means that the penetration of dirt particles and moisture from the outside into the housing is reduced. This leads to increased operating reliability of a correspondingly constructed photovoltaics device according to the invention.

In an advantageous configuration of the photovoltaics device according to the invention, the material, from which the base panel is formed, can be selected such that the base panel has a coefficient of heat expansion, which is close to the coefficient of heat expansion of the side walls.

Base panels with a coefficient of heat expansion, which differs by about 100% to 200%, or by no more than 100% from the coefficient of heat expansion of the side walls, are advantageous. Base panels with a coefficient of heat expansion which differs by no more than 50% from the coefficient of heat expansion of the side walls, are particularly advantageous.

A relatively stable shape and good sealing can be achieved by the selection of a base panel with a coefficient of heat expansion which is close to the coefficient of heat expansion of the side walls, in the photovoltaics device according to the invention, as the side walls expand or contract under temperature fluctuations relatively similarly to the base panel. The position of the base panel with respect to the side walls thus remains relatively constant. As the solar cells are attached to the base panel and the light entrance panel is supported on the side walls, the heat expansion behaviour of the base panel and the side walls in this case leads to a relatively stable position of the light entrance panel with the first optical unit relative to the solar cells, as for an optimal efficiency of the incident direct radiation, the solar cells should always remain positioned in a focal point of the first optical unit. A small displacement of a solar cell relative to a corresponding focal point leads to a large drop in the efficiency of the incident direct radiation and the electrical energy produced by the solar cell.

In an advantageous configuration of the photovoltaics device according to the invention, at least one further panel made of electrically conductive material may be arranged on the inner panel of a bottom panel of the housing or the base panel, the at least one further panel being electrically insulated with respect to the outside of the bottom panel or base panel, and at least one of the solar cells or a sub-group of solar cells being provided on the at least one further panel. The at least one further panel made of electrically conductive material is used as a cathode or anode for a solar cell or as a common cathode or anode for a sub-group of a plurality of solar cells. The use of a panel of this type as a common cathode or anode for a sub-group of solar cells leads to a drop in the number of manufacturing steps in an automated production process for a photovoltaics device according to the invention and thus to lower production prices of a photovoltaics device of this type.

Depending on the construction requirements of the solar system in which a photovoltaics device according to the invention is used, a plurality of such panels with at least one solar cell, used as the cathode or anode of one or more solar cells, can be used. When using the at least one panel made of electrically conductive material, which is electrically insulated with respect to the outside of the bottom panel or base panel of the device according to the invention, the photovoltaics device constructed in this manner is electrically insulated to the outside and thus satisfies one of the safety requirements during photovoltaics device operation.

In an advantageous configuration of the photovoltaics device according to the invention, a plurality of the further panels which are configured with a smaller area relative to the bottom or base panel, may be arranged with a spacing with respect to one another on the bottom or base panel. A plurality of the further panels with a smaller surface area than that of the bottom or base panel, may be arranged in a certain pattern, depending on the operating requirements of a photovoltaics device according to the invention, or a solar system. Preferably, the smaller panels may occupy a plurality of identical part surfaces of the base panel. The use of a plurality of smaller panels with an identical surface area leads to a simplification of automated manufacturing of a corresponding photovoltaics device according to the invention.

In an advantageous configuration of the photovoltaics device according to the invention, the solar cells may be arranged in a regular grid on the at least one further panel or on the smaller panels. Owing to the arrangement of the solar cells in a regular grid on the at least one further panel or on the smaller panels, the further panels or the smaller panels can be prefabricated, depending on the construction requirements, on a photovoltaics device according to the invention, in an automated method, which leads to a simplification and cost reduction of the production of a corresponding photovoltaics device.

In an advantageous configuration of the photovoltaics device according to the invention, the housing may be divided, in particular uniformly, into a plurality of spaces. Thus, it is possible for the housing to be prefabricated in an automated method depending on the construction requirements of a photovoltaics device according to the invention, which leads to a simplification and therefore reduction in the production costs of a corresponding photovoltaics device.

In an advantageous configuration of the advantageous configuration of the photovoltaics device according to the invention, the individual spaces may in each case be covered at the bottom by their own bottom or base panel, in particular can be sealed. The use of a plurality of bottom or base panels means that the spaces can be implemented independently of one another at the bottom depending on the structural requirements of a photovoltaics device according to the invention; in particular this leads to better sealing of the housing from below, which leads to improved protection of the solar cells from environmental influences. Moreover, the heat expansion of the individual panels can be handled better in this manner. Readjustments are more easily possible.

In an advantageous configuration of the photovoltaics device according to the invention, the individual spaces may be covered or sealed at the top in each case by their own light entrance panel with an optical unit. Owing to the covering of the individual spaces at the top in each case by its own light entrance panel with an optical unit, the spaces at the top can be implemented independently of one another depending on the structural requirements of a photovoltaics device according to the invention; in particular, this leads to better sealing of the housing from the top, which leads to improved protection of solar cells from environmental influences. Moreover, owing to this structure, the relative position of an optical unit can be readjusted relative to the corresponding solar cell or solar cells, independently for an individual space or for a plurality of individual spaces. This allows the efficiency of the incident direct radiation onto the solar cells to be increased.

In an advantageous configuration of the photovoltaics device according to the invention, the housing may be provided with intersecting webs on the inside to divide the spaces. The use of intersecting webs is a particularly simple and economical method for dividing the interior of the housing into a plurality of spaces. The webs can also advantageously be used as a support for a light entrance panel and/or bottom panel(s), which further increases the accuracy of position.

In an advantageous configuration of the photovoltaics device according to the invention, the webs may be configured so as to be hollow on the inside and to receive electrical connection lines for the solar cells. Thus, the electrical lines can be insulated and provided spatially separated from the remaining parts of a photovoltaics device according to the invention, which leads to increased operating reliability. Moreover, the webs thus have a double function which leads to economical production of a corresponding photovoltaics device.

Advantageously, the entire housing can be covered and/or sealed at the top with the light entrance panel, thus allowing simplified and economical manufacturing of a photovoltaics device according to the invention.

In addition, the at least one light entrance panel provided with the optical unit and/or a further upper cover panel can be surrounded by a surrounding frame, which is used to seal the upper part of the housing and/or as an identifying means to individualise the outer appearance of the photovoltaics device. By using a surrounding frame for the light entrance panel and/or for the further upper cover panel, the housing can be better sealed from above to thus allow improved protection of the solar cells from environmental influences. The surrounding frame can be constructed such that it can contact an outermost edge surface of the light-facing surface of the light entrance panel and/or the further cover panel and the outer side surface of the further upper cover panel and an outer uppermost side surface of the upper frame of the housing, or of the housing, the outermost edge surface generally being smaller than the contacted side surface. The surrounding frame can simply be fastened by adhesion to the light entrance panel. The maintenance of a corresponding solar system, owing to the individualisation of the individual photovoltaics devices, becomes easier, as well as, for example particularly favourable and simple owing to the dyeing of the surrounding frame as information about PV devices can be divided or allocated to individual PV devices or individual PV device groups and therefore easier to manage and to handle.

Alternatively, the housing may laterally have a valve, which is used to introduce or remove gas and/or vapour into the housing or from the housing. By means of the laterally attached valve, air or steam can be removed from the housing and/or a negative pressure achieved over the solar cells. The presence of less moisture in the direct vicinity of the solar cells and their anodes or cathodes leads to increased operating reliability of a correspondingly constructed PV device. Moreover, the heat transport from the outside to the solar cells by convection is braked by means of the negative pressure produced over the solar cells.

Advantageously, an inert gas can be introduced in a housing, in which a negative pressure has been produced, by means of the valve. The presence of an inert gas over the solar cells protects them from the penetration of moisture and air from the outside into the housing, and because of the lack of reaction of an inert gas, also from corrosion, which leads to an increased operating reliability of the solar cells or a correspondingly constructed PV device.

Advantageously, the optical unit, for each solar cell, may have a lens section, in particular a Fresnel lens section. In this manner, an increased efficiency of the direct radiation incident on the light entrance panel can be achieved.

An advantage of the invention is that a total housing unit, which forms all the side walls, can easily be produced in one piece. The side walls are, for example, a component of a peripheral frame. At the corners, there are no problems in joining the side walls together, and in particular no sealing problems, as there are no joining points.

An embodiment of the invention will be described below with the aid of the accompanying drawing, in which:

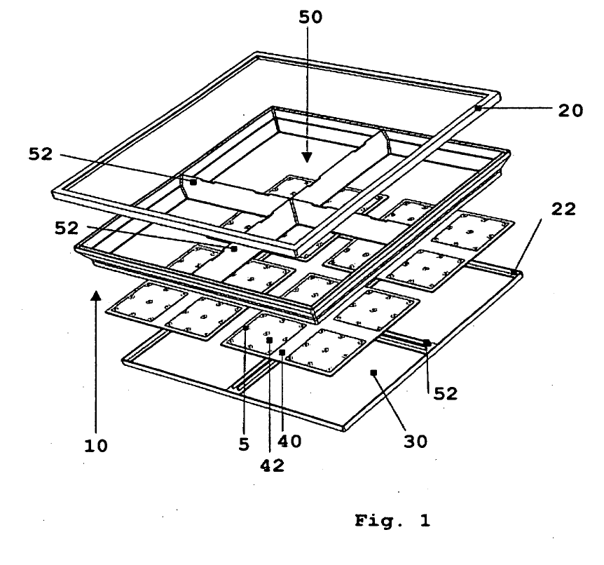

FIG. 1 shows an exploded view of a housing according to the invention with an upper and lower frame, intersecting webs to divide the housing into four spaces, four individual base or bottom panels and a plurality of common anodes or cathodes for a plurality of sub-groups of a plurality of solar cells.

FIG. 1 shows a housing 10 with intersecting webs 52 for dividing the housing 10 into individual spaces 50.

The housing 10 has a peripheral upper frame 20 and a peripheral lower frame 22.

The individual spaces 50 of the housing 10 are covered or sealed at the bottom by individual bottom or base panels 30.

The webs 52 extend in the interior of the housing 10 including the lower frame 22. The webs 52 are hollow in the interior and configured to receive electrical connection lines (not shown) for the solar cells 5.

Furthermore, a further panel 40 is attached on a respective bottom or base panel 30 and is electrically insulated with respect to the outside of the bottom or base panel 30 and is used as a common cathode or anode for a plurality of solar cells 5 arranged in a regular grid on the further panel 40.

The second electrical connection of the solar cell is implemented in each space 50 by a plurality of further small-area panels 42, each further smaller panel 42 being used as a common cathode or anode for a sub-group of a plurality of solar cells, arranged in a regular grid, of the solar cells 5 present in a space 50.

The webs 52 and the four side walls 54, 55, 56, 57 of the housing 10 form an integral unit, which is produced as a component 58 by the injection moulding method from glass fibre-reinforced plastics material.

This injection moulding 58 is provided with a position mark (not shown) in the form of a defined recess at one corner. With the aid of this position mark, the individual parts are allocated in a defined position to one another.

### LIST OF REFERENCE NUMERALS

5 solar cell
10 housing (side walls)
20 upper frame
22 lower frame
30 individual bottom or base panel
40 further panel
42 further smaller panel
50 individual space
52 webs
54 side wall
55 side wall
56 side wall
57 side wall
58 injection moulding

1. Photovoltaics device for the direct conversion of solar energy into electrical energy comprising:
a housing (10), which is provided with at least one light entrance panel formed from a transparent material, a plurality of solar cells (5), which are in each case arranged at a spacing from the at least one light entrance panel on the side thereof remote from the sun in the interior of the housing (10) and take up a smaller surface area than a light entrance surface of the light entrance panel, the light entrance panel being provided with an optical unit to concentrate or focus the solar radiation entering through the light entrance surface onto the smaller surfaces of the solar cells (5), characterised in that the housing (10) has an injection moulding (58) made of a first material to form the side walls.

2. Photovoltaics device according to claim 1, characterised in that the injection moulding (58) is formed from a plastics material mixture.

3. Photovoltaics device according to claim 2, characterised in that the injection moulding (58) is made from a glass-fibre-reinforced plastics material.

4. Photovoltaics device according to claim 5, characterised in that the fibre glass-reinforced plastics material has a glass fibre proportion of 10 to 50% by weight, in particular 30 to 40% by weight.

5. Photovoltaics device according to claim 4, characterised in that the injection moulding (58) is formed from dyed material, in particular dyed plastics material or is subsequently dyed, for example by spraying or dipping.

6. Photovoltaics device according to claim 1 or 5, characterised in that the injection moulding (58) is a metal injection moulding, in particular made of light metal, such as aluminium, or is a part manufactured by the MIM method.

7. Photovoltaics device according to any one of the preceding claims, characterised in that the housing (10) has an additional upper (20) peripheral housing frame (20, 22) facing the light entrance panel and/or a lower peripheral housing frame (22) remote from the light entrance panel, which housing frame is, in particular, configured as an injection moulding.

8. Photovoltaics device according to claim 7, characterised in that the housing (10) has at least one base panel (30) made of a second material on the side opposing the light entrance panel, the second material having greater heat conductivity than the first material.

9. Photovoltaics device according to claim 8, characterised in that the second material is a metal material, such as aluminium or steel, in particular.

10. Photovoltaics device according to any one of the preceding claims, characterised in that the base panel (30) hermetically seals the housing (10) at the bottom and is used for heat dissipation.

11. Photovoltaics device according to any one of the preceding claims, characterised in that the coefficient of heat expansion of the side walls is close to the coefficient of heat expansion of the base panel (30).

12. Photovoltaics device according to any one of the preceding claims, in particular according to claim 8, characterised in that at least one further panel (40) made of electrically conductive material is arranged on the inner panel of a bottom panel (30) of the housing (10) or the base panel (30), the at least one further panel (40) being electrically insulated with respect to the outside of the bottom panel (30) or base panel (30), and in that at least one of the solar cells or a sub-group of the solar cells are provided on the at least one further panel (40).

13. Photovoltaics device according to claim 12, characterised in that a plurality of further panels (40) which have a smaller surface area than the bottom or base panel (30), are arranged at a spacing from one another on the bottom or base panel (30).

14. Photovoltaics device according to claim 13, characterised in that the smaller panels (40) occupy a plurality of identical part surfaces of the base panel (30).

15. Photovoltaics device according to any one of the preceding claims, characterised in that the solar cells (5) are arranged in a regular grid on the at least one further panel (40) or on the smaller panels (40).

16. Photovoltaics device according to any one of the preceding claims, characterised in that the housing (10) is divided, in particular, uniformly into a plurality of spaces (50).

17. Photovoltaics device according to claim 16, characterised in that the individual spaces (50) are in each case covered at the bottom by their own bottom or base panel (30), in particular are sealed.

18. Photovoltaics device according to either of claims 16 or 17, characterised in that the individual spaces (50) are in each case covered at the top by their own light entrance panel with an optical unit, in particular are sealed.

19. Photovoltaics device according to claim 7 and according to any one of claims 16 to 18, characterised in that the housing (10) is provided on the inside with intersecting webs (52) to divide the spaces (50).

20. Photovoltaics device according to claim 19, characterised in that the webs (52) are hollow on the inside and are configured to receive electrical connection lines for the solar cells (5).

21. Photovoltaics device according to any one of claims 16, 17, 19 or 20, characterised in that the entire housing (10) is covered and/or sealed at the top by the light entrance panel.

22. Photovoltaics device according to the preamble of claim 1 or according to any one of the preceding claims, characterised in that the at least one light entrance panel provided with the optical unit, and/or a further upper cover panel is surrounded by a surrounding frame, which is used to seal the upper part of the housing and/or as an identification means to individualise the outer appearance of the photovoltaics device.

23. Photovoltaics device according to any one of the preceding claims, characterised in that the housing (10) laterally has a valve for the introduction of gas and/or vapour into the housing or removal from the housing (10).

24. Photovoltaics device according to claim 23, characterised in that the gas for introduction into the housing (10) is an inert gas.

25. Photovoltaics device according to any one of the preceding claims, characterised in that the optical unit for each solar cell (5) has a lens section, in particular a Fresnel lens section.
